(19) United States
(12) Patent Application Publication
(10) Pub. No.: US 2026/0110974 A1
(43) Pub. Date: Apr. 23, 2026

(54) METHOD FOR CONTROLLING AN OPTICAL MODULE, OPTICAL MODULE AND CONTROL CIRCUIT FOR AN ASSEMBLY OF A PROJECTION EXPOSURE APPARATUS FOR SEMICONDUCTOR LITHOGRAPHY

(71) Applicant: Carl Zeiss SMT GmbH, Oberkochen (DE)

(72) Inventor: Ulrich SCHOENHOFF, Ulm (DE)

(21) Appl. No.: 19/425,701

(22) Filed: Dec. 18, 2025

Related U.S. Application Data
(63) Continuation of application No. PCT/EP2024/065547, filed on Jun. 6, 2024.

(30) Foreign Application Priority Data
Jun. 27, 2023 (DE) 10 2023 116 892.4

(51) Int. Cl. G03F 7/00; G02B 26/08

(52) U.S. Cl. CPC G03F 7/70504; G03F 7/70258; G03F 7/70508; G03F 7/70533; G03F 7/70825; G03F 7/7085; G03F 7/709; G02B 26/0816

(57) ABSTRACT

An optical module of an assembly in an optical system comprises an optical element, a first number of position actuators for positioning the optical element, at least one additional actuator for damping deformations of the optical element caused by the parasitic mechanical disturbances, at least one sensor for determining the pose of the optical element, and a control circuit for controlling the optical element. A method comprises acquiring at least one sensor signal relating to the pose of the optical element, decomposing the at least one acquired sensor signal into a signal group having at least one pose component and a signal group having at least one deformation component, positioning the optical element on the basis of the pose components, and damping the deformations on the basis of the deformation components. A control circuit controls an optical element.

### CROSS-REFERENCE TO RELATED APPLICATIONS

The present application is a continuation of, and claims benefit under 35 USC 120 to, international application No. PCT/EP2024/065547, filed Jun. 6, 2024, which claims benefit under 35 USC 119 of German Application No. 10 2023 116 892.4 of Jun. 27, 2023. The entire disclosure of each of these applications is incorporated by reference herein.

### FIELD

The disclosure relates to a method for controlling an optical module and to a control circuit for controlling an optical element for an optical module. Further, the disclosure relates to an optical module, to an assembly, and to a projection exposure apparatus for semiconductor lithography.

### BACKGROUND

In projection exposure apparatuses of this type, photolithographic methods are used to image microscopically small structures at a greatly reduced size on a wafer coated with photoresist, starting from a mask as template. In subsequent development and further processing steps, the desired structures, for instance memory or logic elements, are created on the wafer, which is then divided into individual chips for use in electronic equipment.

Since the structures to be created are extremely small—down to the nanometer range—relatively extreme demands are placed on the projection exposure apparatus optical systems, and hence on the optical elements, for instance lens elements or mirrors, used in the optical systems, with this applying especially to mirrors on account of the higher optical sensitivity. Mirrors are used within the scope of what is known as EUV lithography, which uses an emission wavelength ranging from 1 nm to 120 nm, especially 13.5 nm, since the lens elements predominantly used at longer wavelengths from 100 nm to 300 nm, i.e., in what is known as the DUV range, are generally no longer transmissive at an emission wavelength of 13.5 nm.

Typically, the utilized mirrors are movable and have such a stiff design that stable positioning of the mirrors without deformation of the optically effective surface, i.e., the surface struck by used light for the purpose of imaging the structure on the wafer, can be ensured during the operation of the apparatus. This type of closed-loop control is also referred to as closed-loop rigid body control since the closed-loop control assumes the mirror to be a rigid, i.e., non-deformable, body.

However, real mirror bodies often exhibit unavoidably quasi-static and dynamic deformations, i.e., time-varying deformations. As the demands on the projection exposure apparatuses are increased from generation to generation, the practical desire for the afforded reduction in unwanted parasitic mechanical disturbances, which cause quasi-static and dynamic deformations of the optically effective surface of the mirror during operation and hence make robust closed-loop pose control for the mirrors more difficult as well, represents an ever more exacting challenge with regards to the closed-loop pose control for the mirrors. In this context, the pose of a body comprises not only the position of the body in space but also the alignment of the body in space; i.e., it describes the body in six mutually independent degrees of freedom.

A quasi-static deformation is distinguished by an equilibrium between the force acting on the optical element and, for instance, bending resulting therefrom. Dynamic deformations, which arise in the region of resonances or natural frequencies of the optical elements for example, are distinguished in that the equilibrium between force and bending is no longer present, and the optical element vibrates back and forth between two states (movement and bending) independently of the external force acting on the optical element, in a manner comparable to a guitar string.

There usually are three sources for the parasitic mechanical disturbances in projection exposure apparatuses.

The parasitic disturbances caused by excitations outside of the projection exposure apparatus, such as floor movements, are a first source. The reaction forces of the actuators used to damp or suppress the external parasitic disturbances, within the scope of what is known as disturbance suppression, should also be assigned to this first source.

These parasitic mechanical disturbances may cause both a rigid body displacement of the optical element itself and a displacement of a sensor reference on the optical element caused by the mirror deformation, which may in turn cause an unwanted rigid body displacement of the optical element on account of the closed-loop control for a target position guided by the sensors.

Reaction forces arising from conventional scanning during exposure in the current projection exposure apparatuses, i.e., a displacement of the reticle and the wafer in opposite directions vis-à-vis a projection optical unit, are a second source. The wafer and the reticle are displaced together with their mount, the so-called reticle stage and wafer stage. Their acceleration forces may propagate to the optical element in the process, similar to the reaction forces from the disturbance suppression.

Fluid channels through which a fluid flows for the purpose of cooling components and/or optical elements may be a third source of parasitic mechanical disturbances. Firstly, the fluid can transmit parasitic mechanical disturbances in the form of vibrations and, secondly, cause parasitic mechanical disturbances itself, for instance at cross-sectional transitions or bends in the fluid channel.

The parasitic mechanical disturbances may lead to an excitation of eigenmodes of the optical element, whereby comparatively large amplitudes are sensed by the respective position sensors and fed back to the closed-loop pose control of the mirror as a consequence of the relatively low damping in the control loop in the region of the eigenmodes, whereby the stability of the control loop is compromised, and an active closed-loop pose control of the rigid body can no longer be operated in stable fashion or only with low control quality.

The German patent application DE 10 2013 201 082 A1 describes a solution approach which counteracts the described issue by virtue of over-actuating and optionally over-sensing, i.e., arranging additional actuators (and sensors) for positioning the optical element, with the intention being to arrange the actuators (and sensors) at the nodes of specific eigenmodes for example.

However, in this approach the actuators for avoiding eigenmode excitations are arranged at least in one eigenmode node. Furthermore, the additional actuators are used to position the optical element, i.e., distribute the forces for positioning the optical element to all available actuators. This means that additional static forces are applied to the mirror body and these may cause a static deformation of the optically effective surface. Furthermore, the solution approach disclosed may be completely unable to damp the flexible modes of the optical element during closed-loop pose control.

### SUMMARY

The present disclosure seeks to provide an improved method.

The present disclosure seeks to provide an improved control circuit for controlling an optical module.

The present disclosure seeks to provide an improved optical module.

In an aspect, the disclosure provides a method for controlling an optical module of an assembly in a projection exposure apparatus for semiconductor lithography
having an optical element,
a first number of position actuators for positioning the optical element,
at least one additional actuator for damping deformations of the optical element caused by the parasitic mechanical disturbances,
at least one sensor for determining the pose of the optical element, and
a control circuit for controlling the optical element,
   comprises the following method steps:
acquiring at least one sensor signal relating to the pose of the optical element,
decomposing the at least one acquired sensor signal into a signal group having at least one pose component and a signal group having at least one deformation component,
positioning the optical element on the basis of the pose components, and
damping the deformations on the basis of the deformation components.

The method can help reduce the influence of the parasitic mechanical disturbances-induced quasi-static and dynamic optical element deformations on the closed-loop control quality and stability and on the optical element imaging quality. Decomposing the acquired sensor signals which relate to the pose and, depending on the optical module embodiment, to the deformation of the optically effective surface of the optical element as well can help allow, firstly, the application of closed-loop pose control known from the prior art and, secondly, damping of the parasitic deformations using additional actuators that engage on the optical element. On account of the type of parasitic mechanical disturbances, the deformations are formed as time-varying deformations (quasi-static, dynamic) or as time-varying rigid body movements (dynamic), the amplitudes of which are damped according to the disclosure by the control circuit. A control circuit in the context of the disclosure should be understood to mean, for example, the closed-loop and open-loop control structure or architecture of the control circuit.

The parasitic components of the sensor signal fed back to the closed-loop pose control which are caused by the deformations (quasi-static, dynamic) via a displacement of the position sensor connection points on the optical element can be damped as a result, whereby the influence on the stability of the closed-loop controller is minimized, and the optical element pose can be controlled with a higher bandwidth under comparable closed-loop controller stability. Additionally, quasi-static and dynamic deformations which may have a negative influence on the optical element imaging quality are avoided. According to the disclosure, a closed-loop pose control and a closed-loop damping control can be based on mutually independent controlled variables, with both control loops being able to access all actuators as possible final controlling elements.

In a first embodiment, the at least one sensor signal can be decomposed by a first static transformation matrix. The signals from the conventionally six position sensors for closed-loop pose control of the optical element in six degrees of freedom and the sensor signals from additional sensors for sensing the optical element deformation can be transformed from a sensor coordinate system into a coordinate system based on a reference point on the optical element, which may for instance be in the form of a mirror, via the static transformation matrix and can be decomposed into two signal groups in the process.

The decomposition may include a modal decomposition, in which the modal eigenmodes of the optical element are initially determined on the basis of the acquired position signals. These comprise six rigid body movements, i.e., movements of the optical element along an axis or a rotation of the optical element as a rigid body about an axis, with the optical element not being deformed. These rigid body modes correspond to the pose component.

The further eigenmodes relate to a deformation of the optical element, for instance in the form of a mirror, and are also referred to as flexible modes. These correspond to the deformation component.

The individual modes of the signal groups can be independent of one another, whereby a closed-loop pose controller formed in the closed-loop pose control and a closed-loop damping controller can be configured as mutually independent single-variable systems for each degree of freedom. Single-variable systems or SISO (single input single output) systems can be distinguished by one input variable and one output variable, and therefore are comparatively simple closed-loop controllers, whereby the closed-loop control complexity can be reduced.

In an embodiment, the decomposition can be implemented by an observer. In control engineering, an observer is a system which takes known input variables, for instance actuator positioning forces, and output variables, for instance sensor signals relating to the pose of an optical element (measured variable) in an observed reference system, in order to reconstruct non-measurable variables, for instance optical element deformations (states). To this end, the observer can simulate the observed reference system as a model and uses a closed-loop controller to adjust the measurable state variables, which are therefore comparable to the reference system. The intention is thus to prevent a model from generating an error that grows over time, especially in the case of reference systems with integrating behavior. According to the disclosure, the observer can reconstruct both the rigid body movement and the quasi-static and/or dynamic deformations, which for example are decomposed into mutually independent eigenmodes of the optical element. The observer can mean that the position signals for determining the optical element pose, which are present in the case of an optical module with a positionable optical element, are sufficient. Thus, the observer might not be reliant on additional sensors for sensing the deformation.

For example, the observer may comprise an adaptive model which allows an adaptation of the model used for reconstructing the unknown states (deformations). This can allow a continual adaptation of the model on the basis of control qualities sensed during the operation.

In an embodiment, the decomposition can be implemented by a multivariable system. A multivariable system or MIMO (multiple input multiple output) system uses a plurality of mutually dependent input variables and output variables, which gives rise to a greater complexity of the closed-loop control. In principle, a multivariable system is also based on a status regulator, just like the observer, wherein the multivariable system is based on an H-infinity synthesis or a μ-synthesis. The multivariable system is mathematically more complex, wherein, nevertheless, the fed-back sensor signals are decomposed into a signal group having at least one pose component and a signal group having at least one deformation component. Like the observer, the multivariable system means that no additional sensors are used.

In an embodiment, the closed-loop pose control can be carried out by a closed-loop pose controller, and the damping can be controlled by a closed-loop damping controller which is independent of the closed-loop pose controller. The independent closed-loop damping controller can bring about the ability to damp the parasitic components of the sensor signals which might be relevant to the stability of the closed-loop controller and which are caused by the quasi-static and dynamic deformations. A higher control bandwidth with unchanged stability of the closed-loop controller can be chosen as the damping of the deformations improves, whereby the suppression of the closed-loop control deviation of the closed-loop pose control can be improved. Furthermore, the closed-loop damping controller has the capability of damping the mechanical vibrations caused by interferences affecting the optical element. For instance, in the case of an optical element in the form of a mirror, these may be flow noises occurring in the mirror cooling system or disturbance forces that are transferred due to the finite stiffness of gravity compensators present to assist the position actuators.

Furthermore, the closed-loop pose controller and the closed-loop damping controller may each create actuator signals for controlling position actuators for closed-loop pose control and additional actuators for damping. Thus, in principle, all actuators can be used for closed-loop pose control and for damping the deformations. For the closed-loop pose controller, this can reduce the flexible mode excitation when the rigid body modes are actuated. As explained further above, the fed-back sensor signals can be subdivided into signal groups which can be transmitted to a closed-loop pose controller and a closed-loop damping controller as independent controlled variables.

Furthermore, the actuator signals for closed-loop pose control of the optical element may comprise at least one static component. The static component of the actuator signals for closed-loop pose control may cause the position to be kept stable within the scope of the system deviation. For instance, the static components can be created in the actuator signals by way of an integrating component which is used in the closed-loop pose controller and encompassed by a PID controller usually used for closed-loop pose control.

For example, the actuator signals for damping the quasi-static and dynamic deformations caused by the parasitic mechanical disturbances can be filtered such that these exclusively comprise quasi-static and/or dynamic components. For instance, the static components of the actuator signals for damping can be filtered from the actuator signals by way of a frequency filter, as a result of which only the quasi-static and dynamic components remain in the actuator signals. This means that static deformations, which would also have a static deformation as a consequence, cannot be created by the additional actuators. For instance, the frequency filter can be designed as a high-pass filter having a cutoff frequency of 30 Hz, for example. The static components can be applied, optionally in statically determined fashion, by way of the position actuators. To this end, the position actuators can act on the same points of application of force as the gravity compensators, and so a statically determined bearing of the optical element can be achieved.

In an embodiment, the actuator signals for closed-loop pose control and for damping can be decomposed into two signal groups on the basis of frequencies. On the one hand, this allows the positioning forces of the actuators to be assigned to the most suitable actuator in frequency-dependent fashion. On the other hand, it is also possible to reduce the effects of the reaction forces from other actuators, especially in the case where inertial actuators are used as additional actuators. This means that an inertial actuator does not apply reaction forces to a frame or any other structure, whereby the inertial actuator is able to suppress the reaction path from other actuators which apply a reaction force to a frame or a structure. Thus, an embodiment may be such that each position actuator or frame actuator, i.e., especially those actuators which cause a reaction force on a frame or a structure, to be supplemented by the arrangement of an inertial actuator in the immediate vicinity. Thus, the closed-loop pose control can be implemented with the best-possible suppression of the reaction forces over the relevant frequency range; this has a positive effect on the control quality of the closed-loop pose control. The same also applies to the closed-loop damping controller and the actuators used for damping.

In an embodiment, a parasitic component, caused by the deformation of the optical element, of the position signal acquired by the at least one position sensor can be determined. Parasitic components of the position components are created if the position of the position sensor measurement location in space is modified on account of a mirror deformation and not on account of a mirror rigid body movement in space. The position sensor itself is unable to distinguish between the causes of the sensed position change, which can be quasi-static or dynamic (static).

For example, the parasitic components of the closed-loop pose control can be fed back. This can prevent would-be pose errors based on parasitic position signal components from reaching the closed-loop pose controller; instead, they are already combined by calculation with the acquired position signals when the position signals are decomposed into the two signal groups, as explained further above. The signal group fed back to the closed-loop pose controller no longer contains the parasitic position signal components, whereby the closed-loop control can be operated with a higher control bandwidth with unchanged stability.

A control circuit according to the disclosure for controlling an optical element for an optical module of an assembly in a projection exposure apparatus for semiconductor lithography comprises closed-loop pose control which is designed to use at least one fed-back sensor signal relating to the pose of the optical element as a basis for creating a first signal group as feedback for the closed-loop pose control of the optical element.

According to the disclosure, a control circuit may be distinguished in that the closed-loop pose control is also designed to use the at least one fed-back sensor signal relating to the pose of the optical element as a basis for creating a second signal group as feedback for damping deformations of the optical element caused by mechanical disturbances. This makes it possible that the disturbances which are fed-back to the closed-loop pose controller due to the deformations (static, quasi-static, dynamic) and via the sensors are damped, whereby the position can be controlled with a higher controlled bandwidth with comparable stability.

In addition, quasi-static and dynamic deformations of the optically effective surface of the optical element, which have a negative influence on the projection exposure apparatus imaging quality, are reduced or prevented entirely. In this case, the first and the second signal group can be formed independently of one another; thus, for instance, the first signal group can comprise six degrees of freedom of the optical element rigid body movement and the second signal group can comprise the flexible eigenmodes, i.e., the eigenmodes relating to an optical element deformation.

Furthermore, the control circuit may comprise a first transformation matrix for creating the first and the second signal group. As further above, the signal groups are created by a modal decomposition.

In an embodiment, the control circuit may comprise an observer, which has already been explained further above, for creating the first and the second signal group.

In an embodiment, the control circuit may comprise a multivariable controller, which has already been explained further above, for creating the first and the second signal group.

For example, the multivariable controller may be based on an H-infinity synthesis or a μ-synthesis. The H-infinity synthesis assumes that the control task is formulated as an optimization problem. This means that there is broad applicability in the field of SISO and MIMO systems, especially for closed-loop controls, the extensibility to nonlinear problems and, in the case of good design, very robustly performant closed-loop control results while simultaneously ensuring the stability. In the case of model-based closed-loop controllers, uncertainties arising due to the model creation are always included in the closed-loop control. Control can be referred to as robust if it is insensitive to these model inaccuracies, i.e., if the control quality is not significantly impaired or let alone the stability is compromised. The basis for the H-infinity synthesis is the modeling of the known model uncertainties; this leads to an extended transfer function which then forms the basis for the numerical calculation of the closed-loop controller based on the H-infinity synthesis. The μ-synthesis extends the H-infinity synthesis by the option of a more differentiated description of the structure of the model inaccuracies, and thus of obtaining a higher control quality with equal robustness.

In an embodiment, the closed-loop pose control may comprise a closed-loop pose controller for positioning the optical element and a closed-loop damping controller for damping the deformations. Both closed-loop controllers can be configured as PID controllers, wherein, for the purpose of closed-loop control of the static pose of the optical element, the closed-loop pose controller uses all three components for closed-loop control purposes. By contrast, the P-controller and I-controller are optional in the case of the closed-loop damping controller.

Furthermore, the control circuit may comprise a further static transformation matrix for transforming the actuator signals created in the closed-loop pose controller and closed-loop damping controller. In a manner comparable to the transformation matrix for modal decomposition already explained further above, the transformation matrix can transform the actuator signals from the optical element coordinate system into an actuator coordinate system.

In an embodiment, the closed-loop pose controller may comprise a first frequency filter for eliminating the static components from the actuator signals created for damping the deformations. As already explained further above in the context of the signal groups of the actuator signals, the frequency filter in the branch of the actuator signals for damping the deformations can be formed as a high-pass filter with a cutoff frequency of 30 Hz.

This has the effect that static components are no longer transmitted to the actuators, and so a static deformation of the optical element can be avoided.

Furthermore, the control circuit may comprise a further frequency filter for subdividing the actuator signals into low-frequency signals and high-frequency signals. As already explained further above, the latter serves to distribute the frequency-dependent positioning forces among the actuators with the best correspondence and can be desirable, especially when inertial actuators are used.

In addition, the control circuit may comprise a further frequency filter for combining the at least one sensor signal relating to the pose of the optical element and a sensor signal from an inertial sensor. The combination creates a position signal over the entire frequency range sensed by the two sensors, and this is a basic precondition for the modal decomposition of the sensor signals already explained.

In an embodiment, the control circuit can comprise a motion profile generator. The latter can provide the closed-loop pose control with a time profile of a signal group with a position target value and a signal group with accelerations as input variables for each position actuator for closed-loop rigid body control. The position target value and acceleration are determined on the basis of an optical element movement trajectory based on the current target value and its subsequent target value. Thus, the movement trajectory describes the planned movement of the optical element from the current target position to the subsequent target position which deviates from the current target position. Subsequently, consistent time profiles of route and acceleration of the optical element are determined from the movement trajectory.

In this case, the respective target value can be transmitted directly to the closed-loop controller as a target value, wherein the time profile of the acceleration can be used to determine, according to F=m*a, the forces to change the pose of the optical element from the current target position to the subsequent target position. At addition points of the control circuit downstream of the closed-loop pose controller and closed-loop damping controller, the forces determined thus are added to the actuator positioning forces ascertained in the controllers, with the result that the positioning of the optical element from the current target position to the subsequent target position can be anticipated. This means that the pose deviation of the optical element from the subsequent target position need not be sensed by sensors and then corrected by the closed-loop pose controller; instead, this is already homed in on by the additional force at the same time as the subsequent target value transmission. As a result, the closed-loop pose controller thus still only needs to correct the pose deviations caused by disturbances in the controlled system. In an embodiment, the control circuit may comprise open-loop deformation control. The latter may specify a static deformation which is controlled by the closed-loop pose control.

For example, the control circuit may comprise a deformation profile generator (=for the targeted deformation of the optically effective surface). The latter may create the predetermined optical element deformation profiles, which are desired for correcting aberrations, and transfer these to the open-loop deformation control. The open-loop deformation control is independent of the closed-loop pose control with the closed-loop pose controller and the closed-loop damping controller and can be used optionally, wherein the deformation may in turn also be caused by the additional actuators.

In an aspect, the disclosure provides an optical module according to the disclosure of an assembly in an optical system, the optical module comprising:
an optical element,
a first number of position actuators for positioning the optical element,
at least one additional actuator for damping deformations of the optical element caused by mechanical disturbances,
at least one sensor for determining the pose of the optical element, and
a control circuit for controlling the optical element.

This makes it possible that, firstly, the pose of the optical element can be controlled with a high control bandwidth by a closed-loop pose control under the assumption of an optical element in the form of a rigid body and, secondly, the deformations caused by the parasitic mechanical disturbances can be damped. As a result, the quasi-static and dynamic deformations have only a smaller influence, or no influence, on the optical module imaging quality. The additional damping actuators can also be used to assist the closed-loop pose control, just like the position actuators can be used to damp the deformations. According to the disclosure, the closed-loop pose control and the closed-loop damping control is based on mutually independent controlled variables (modal decomposition), with both control loops accessing all actuators as possible final controlling elements.

For example, position actuators and additional damping actuators can be designed as one of the following actuator types:

Lorentz actuators, inertial actuators, reluctance actuators, piezoelectric actuators, electrostrictive actuators, magnetostrictive actuators and/or shape memory actuators. In this case, the use of the actuator types as position actuator and damping actuator depends on their desired properties and can be chosen freely as a matter of principle. Any of the aforementioned actuator types can thus be used for a position actuator or a damping actuator, and different actuator types can also be used for different position actuators and damping actuators.

In an embodiment, the optical module may comprise at least one additional sensor. For example, the additional sensors may be used for acquiring the deformations.

For example, the at least one additional sensor can be designed as one of the following sensor types: interferometers, frequency-based optical sensors, capacitive sensors, strain sensors, for example strain gauges or fiber Bragg sensors, inertial sensors, for example piezoelectric, MEMS or MEOEMS acceleration sensors, or geophones.

In an embodiment, the optical module may comprise deformation actuators. Deformation actuators within the meaning of the disclosure are actuators supported on the optical element on both sides; i.e., they do not transfer any reaction forces to a frame or a structure. An expansion or a contraction of a deformation actuator results in a bending-type deformation of the optically effective surface. The deformation actuator label serves primarily to distinguish between different actuator types with different functions and is not restricted to a specific operational principle. The operational principles are the same as for the position actuators or the other damping actuators.

Furthermore, the optical module may comprise deformation sensors. Deformation sensors within the meaning of the disclosure are sensors which are defined by the connection of both sensor sides to the optical element. The deformation sensor label serves primarily to distinguish between different sensor types with different functions and is not restricted to a specific type of sensor types. The operational principles are the same as for the position actuators or frame actuators.

An assembly according to the disclosure comprises an optical module according to one of the explained embodiments and/or a control circuit according to one of the explained embodiments.

An optical system according to the disclosure, especially a projection exposure apparatus for semiconductor lithography, comprises an assembly according to one of the explained embodiments.

The mechanical disturbances mentioned can be quasi-stationary or low-frequency disturbances for example.

### BRIEF DESCRIPTION OF THE DRAWINGS

Exemplary embodiments and variants of the disclosure are explained in detail below with reference to the drawing, in which:

FIG. 1 schematically shows a meridional section of a projection exposure apparatus for EUV projection lithography,

FIG. 2 schematically shows a meridional section of a projection exposure apparatus for DUV projection lithography,

FIGS. 3A-3C show schematic illustrations for elucidating various components that occur during the movement of an optical element,

FIG. 4 shows a schematic illustration of an optical module according to the disclosure,

FIG. 5 shows a schematic illustration of a control circuit according to the disclosure,

FIG. 6 shows a first embodiment of an assembly according to the disclosure with an optical module and a control circuit,

FIG. 7 shows a further embodiment of an assembly according to the disclosure,

FIG. 8 shows a further embodiment of an assembly according to the disclosure,

FIG. 9 shows a further embodiment of an assembly according to the disclosure,

FIG. 10 shows a further embodiment of an assembly according to the disclosure, and

FIG. 11 shows a further embodiment of an assembly according to the disclosure.

### DETAILED DESCRIPTION

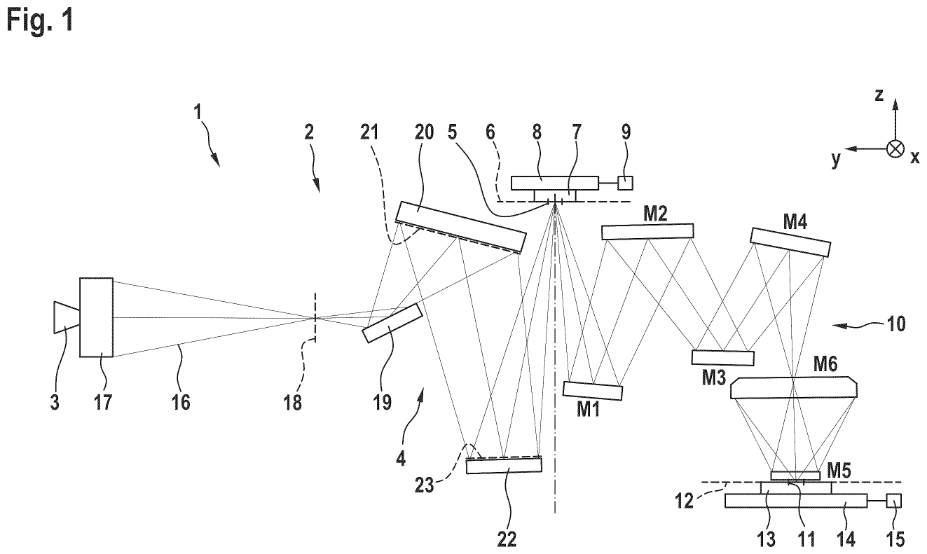

Certain constituent parts of a microlithographic projection exposure apparatus 1 are described in exemplary fashion below, initially with reference to FIG. 1. The description of the basic structure of the projection exposure apparatus 1 and its constituent parts are understood to be non-limiting in this respect.

An embodiment of an illumination system 2 of the projection exposure apparatus 1 has, in addition to a radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable, for example in a scanning direction, by way of a reticle displacement drive 9.

FIG. 1 shows a Cartesian xyz-coordinate system for explanatory purposes. The x-direction runs perpendicular to the plane of the drawing. The y-direction runs horizontally, and the z-direction runs vertically. The scanning direction runs along the y-direction in FIG. 1. The z-direction runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable, for example along the y-direction, by way of a wafer displacement drive 15. The displacement on the one hand of the reticle 7 by way of the reticle displacement drive 9 and on the other hand of the wafer 13 by way of the wafer displacement drive 15 may take place in such a way as to be synchronized with one another.

The radiation source 3 is an EUV radiation source. The radiation source 3 emits, for example, EUV radiation 16, which is also referred to below as used radiation, illumination radiation or illumination light. For example, the used radiation has a wavelength in the range between 5 nm and 30 nm. The radiation source 3 may be a plasma source, for example an LPP (laser produced plasma) source or a GDPP (gas discharge produced plasma) source. It can also be a synchrotron-based radiation source. The radiation source 3 can be a free electron laser (FEL).

The illumination radiation 16 emerging from the radiation source 3 is focused by a collector 17. The collector 17 may be a collector with one or more ellipsoidal and/or hyperboloid reflection surfaces. The illumination radiation 16 can be incident on the at least one reflection surface of the collector 17 with grazing incidence (GI), i.e., at angles of incidence of greater than 45° relative to the direction of the normal to the mirror surface, or with normal incidence (NI), i.e., at angles of incidence of less than 45°. The collector 17 can be structured and/or coated on the one hand for optimizing its reflectivity for the used radiation and on the other hand for suppressing extraneous light.

The illumination radiation 16 propagates through an intermediate focus in an intermediate focal plane 18 downstream of the collector 17. The intermediate focal plane 18 may represent a separation between a radiation source module, having the radiation source 3 and the collector 17, and the illumination optical unit 4.

The illumination optical unit 4 comprises a deflection mirror 19 and, downstream thereof in the beam path, a first facet mirror 20. The deflection mirror 19 may be a plane deflection mirror or, alternatively, a mirror with a beam-influencing effect that goes beyond the pure deflection effect. In an alternative or in addition, the deflection mirror 19 may be designed as a spectral filter that separates a used light wavelength of the illumination radiation 16 from extraneous light at a different wavelength. If the first facet mirror 20 is arranged in a plane of the illumination optical unit 4 that is optically conjugate to the object plane 6 as a field plane, it is also referred to as a field facet mirror. The first facet mirror 20 comprises a plurality of individual first facets 21, which are also referred to below as field facets. FIG. 1 depicts only some of the facets 21 by way of example.

The first facets 21 can be in the form of macroscopic facets, for example in the form of rectangular facets or in the form of facets with an arcuate edge contour or an edge contour formed as partly circular. The first facets 21 may be in the form of plane facets or alternatively in the form of convexly or concavely curved facets.

As is known for example from DE 10 2008 009 600 A1, the first facets 21 themselves can also each be composed of a multiplicity of individual mirrors, for example a multiplicity of micromirrors. For example, the first facet mirror 20 can be in the form of a microelectromechanical system (MEMS system). For details, reference is made to DE 10 2008 009 600 A1.

The illumination radiation 16 travels horizontally, i.e., along the y-direction, between the collector 17 and the deflection mirror 19.

In the beam path of the illumination optical unit 4, a second facet mirror 22 is arranged downstream of the first facet mirror 20. Provided the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal periphery, or may alternatively be facets composed of micromirrors. In this regard, reference is likewise made to DE 10 2008 009 600 A1.

The second facets 23 can have plane or, alternatively, convexly or concavely curved reflection surfaces.

The illumination optical unit 4 consequently forms a doubly faceted system. This basic principle is also referred to as a fly's eye integrator.

It may be desirable to arrange the second facet mirror 22 not exactly in a plane that is optically conjugate to a pupil plane of the projection optical unit 10. For example, the pupil facet mirror 22 may be arranged so as to be tilted relative to a pupil plane of the projection optical unit 10, as described, for example, in DE 10 2017 220 586 A1.

The individual first facets 21 are imaged into the object field 5 using the second facet mirror 22. The second facet mirror 22 is the last beam-shaping mirror or else indeed the last mirror for the illumination radiation 16 in the beam path upstream of the object field 5.

In a further embodiment (not illustrated) of the illumination optical unit 4, a transfer optical unit may be arranged in the beam path between the second facet mirror 22 and the object field 5, and contributes for example to the imaging of the first facets 21 into the object field 5. The transfer optical unit may have exactly one mirror or, alternatively, also two or more mirrors, which are arranged in succession in the beam path of the illumination optical unit 4. The transmission optical unit can for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20 and the pupil facet mirror 22.

The deflection mirror 19 may also be omitted in a further embodiment of the illumination optical unit 4, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The second-last mirror M5 and the last mirror M6 each have a through opening for the illumination radiation 16. The projection optical unit 10 is a doubly obscured optical unit. The projection optical unit 10 has an image-side numerical aperture which is greater than 0.5 and which can also be greater than 0.6 and which, for example, can be 0.7 or 0.75.

Reflection surfaces of the mirrors Mi can be in the form of free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings may be in the form of multi-layer coatings, for example with alternating layers of molybdenum and silicon.

The projection optical unit 10 has a large object-image offset in the y-direction between a y-coordinate of a center of the object field 5 and a y-coordinate of the center of the image field 11. In the y-direction, this object-image offset can be of approximately the same magnitude as a z-distance between the object plane 6 and the image plane 12.

The projection optical unit 10 may for example have an anamorphic form. For example, it has different imaging scales βx, βy in the x- and y-directions. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, i.e., in a direction perpendicular to the scanning direction.

The projection optical unit 10 leads to a reduction in size of 8:1 in the y-direction, which is to say in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 may be the same or may be different depending on the design of the projection optical unit 10. Examples of projection optical units with different numbers of such intermediate images in the x-and y-directions are known from US 2018/0074303 A1.

One of the pupil facets 23 in each case is assigned to exactly one of the field facets 21, in each case to form an illumination channel for illuminating the object field 5. For example, this can produce illumination according to the Köhler principle. The far field is deconstructed into a multiplicity of object fields 5 using the field facets 21. The field facets 21 create a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is for example as homogeneous as possible. It can have a uniformity error of less than 2%. Field uniformity can be achieved by overlaying different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, for example the subset of the pupil facets that guide light. This intensity distribution is also referred to as illumination setting.

A likewise preferred pupil uniformity in the region of portions of an illumination pupil of the illumination optical unit 4 that are illuminated in a defined way can be achieved by a redistribution of the illumination channels.

Further aspects and details of the illumination of the object field 5 and for example of the entrance pupil of the projection optical unit 10 are described below.

The projection optical unit 10 may have a homocentric entrance pupil for example. The latter can be accessible. It can also be inaccessible.

The entrance pupil of the projection optical unit 10 generally cannot be illuminated exactly via the pupil facet mirror 22. The aperture rays often do not intersect at a single point in the event of imaging by the projection optical unit 10, which telecentrically images the center of the pupil facet mirror 22 onto the wafer 13. However, it is possible to find an area in which the distance of the aperture rays determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, for example an optical component part of the transfer optical unit, should be provided between the second facet mirror 22 and the reticle 7. With the aid of this optical element, the different pose of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged with a tilt in relation to the object plane 6. The first facet mirror 20 is arranged with a tilt in relation to an arrangement plane defined by the deflection mirror 19.

The first facet mirror 20 is arranged with a tilt in relation to an arrangement plane defined by the second facet mirror 22.

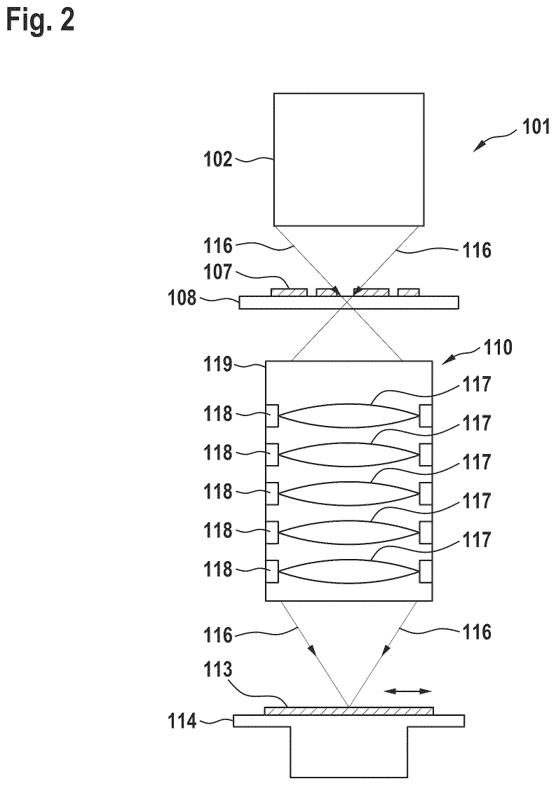

FIG. 2 schematically shows a meridional section through a further projection exposure apparatus 101 for DUV projection lithography, in which the disclosure can likewise be used.

The structure of the projection exposure apparatus 101 and the principle of the imaging are comparable with the structure and procedure described in FIG. 1. Identical structural parts are denoted by a reference sign increased by 100 with respect to FIG. 1, i.e., the reference signs in FIG. 2 start at 101.

By contrast to an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, for example in the region of 193 nm. The projection exposure apparatus 101 in this case comprises an illumination system 102, a reticle holder 108 for receiving and exactly positioning a reticle 107 provided with a structure, the reticle determining the later structures on a wafer 113, a wafer holder 114 for holding, moving, and exactly positioning this wafer 113, and a projection lens 110, with multiple optical elements 117, which are held by way of mounts 118 in a lens housing 119 of the projection lens 110.

The illumination system 102 provides DUV radiation 116 used for the imaging of the reticle 107 on the wafer 113. A laser, a plasma source or the like can be used as the source of this radiation 116. The radiation 116 is shaped in the illumination system 102 via optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the structure of the downstream projection optical unit 101 with the lens housing 119 fundamentally does not differ from the structure described in FIG. 1 and is therefore not described in more detail.

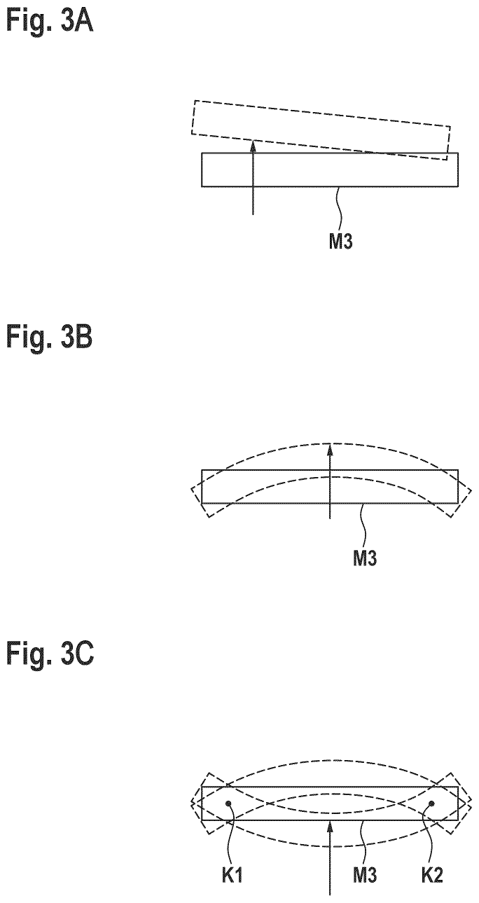

FIGS. 3A to 3C show schematic illustrations of different movement components of an optical element designed as mirror M3, as can be used in the projection exposure apparatus 1 explained in relation to FIG. 1. The movement components are caused by mechanical disturbances that act on the not ideally stiff mirror M3 and can be subdivided into three groups.

FIG. 3A shows a purely parasitic dynamic rigid body movement of the mirror M3, which corresponds to the movement of an ideally stiff mirror M3 in which no mirror M3 deformations occur. The rigid body movements usually comprise three mutually orthogonal translational degrees of freedom and three rotational degrees of freedom about the orthogonal axes of the translational degrees of freedom, for instance an x-axis, y-axis, and z-axis in a Cartesian coordinate system.

FIG. 3B shows a parasitic quasi-static deformation of the mirror M3, wherein quasi-static is distinguished by an equilibrium between a mechanical disturbance acting on the mirror M3, for instance a force, and bending resulting therefrom which nevertheless varies over time.

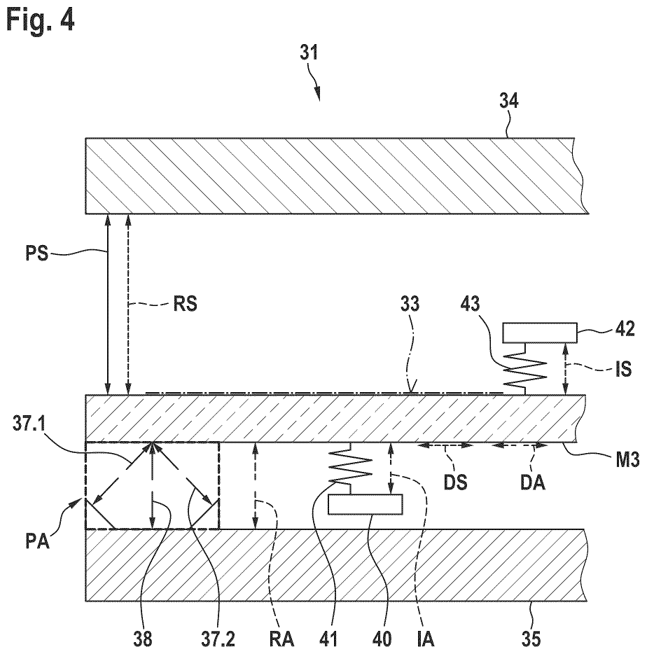

FIG. 3C shows a parasitic dynamic deformation of the mirror M3 in an exemplary eigenmode with two nodes K1, K2. Dynamic deformations arise in the region of the resonances or the natural frequencies of the optical elements for example and, in contrast to the quasi-static deformations, are distinguished in that there is no equilibrium between a mechanical disturbance and bending, and the optical element vibrates dynamically between two states (movement and bending) independently of the force acting on the optical element, in a manner comparable to a spring pendulum. The eigenmode may also be in the form of a rigid body movement. All three movement components (rigid body, quasi-static, dynamic) lead to a deterioration in the imaging quality, wherein the rigid body movement causes a change in the image which is constant over the image representation, for instance a displacement. In the case of low frequencies below a predetermined cutoff value, the quasi-static and dynamic deformations lead to a change that varies over the image representation, for example a differently large displacement of individual points in the image representation. By contrast, quasi-static and dynamic deformations at a frequency above the predetermined cutoff value lead to image blurring. FIG. 4 shows a schematic illustration of an optical module according to the disclosure in the form of a mirror module 31. The mirror module 31 comprises an optical element which is designed as a mirror M3, connected to a force frame 35 by way of a position actuator unit PA and able to be positioned relative to the force frame, as can be used in a projection exposure apparatus 1 explained in relation to FIG. 1. The schematic illustration in FIG. 4 shows only one of generally three position actuator units PA, which are arranged such that the mirror M3 can be displaced in six degrees of freedom. The mirror M3 has an optically effective surface 33, to which used radiation 16 (FIG. 1) is applied during the operation of the projection exposure apparatus 1 (FIG. 1) for the purpose of imaging the structures and the pose and geometry of which is decisive for the imaging quality of the projection exposure apparatus 1.

The position actuator unit PA is designed as a bipod and, in the embodiment shown in FIG. 4, comprises a weight compensator 38 and two actuators 37.1, 37.2, which are arranged at an angle of, for instance, 90° with respect to one another and which may be in the form of Lorentz actuators, for example. In this case, the actuators 37.1, 37.2 are supported on the force frame 35.

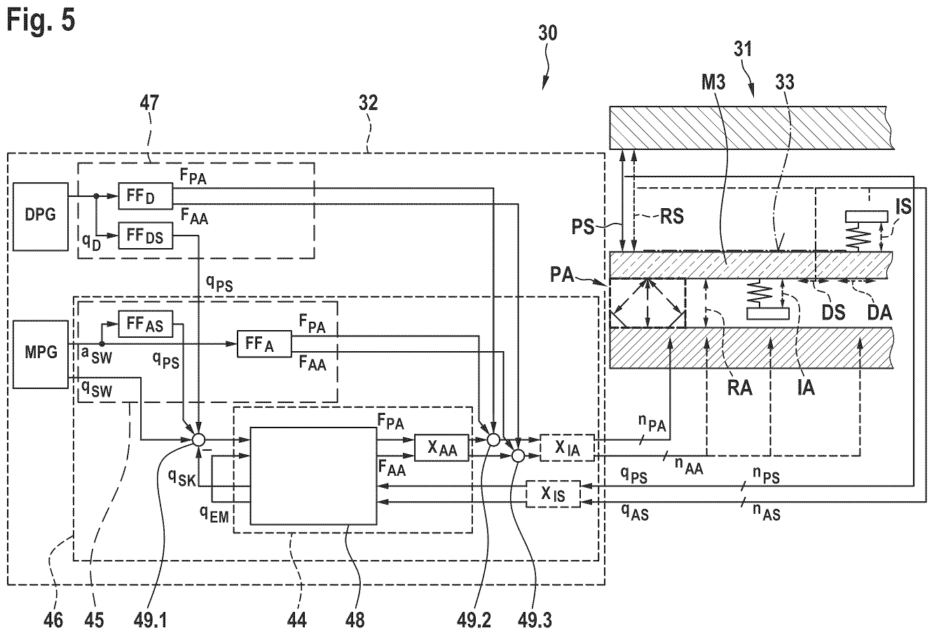

The optical module 31 also comprises a position sensor unit PS which, by way of at least six sensors assigned to the position sensor unit PS, determines the position and alignment of the mirror M3 in six degrees of freedom vis-à-vis a reference frame 34 which serves as a reference for determining the pose of the mirror M3. In due course, the reference sign PS will also be used for the sensors of the position sensor unit PS, especially in the context of the additional sensors RS, DS, IS. The position actuator unit PA and the position sensor unit PS are connected to a control circuit 32 (FIG. 5) explained in detail in FIG. 5, and thus allow the mirror M3 to be positioned relative to the reference frame 34 in six degrees of freedom.

All actuators 37.1, 37.2, RA, DA, IA and sensors PS, RS, DS, IS are depicted as arrows in FIG. 4. The actuators 37.1, 37.2, RA, DA, IA are depicted as two oppositely directed arrows in each case, representing firstly an actuator force acting on the mirror M3 and secondly a reaction force acting in the opposite sense. The sensors PS, RS, DS, IS are depicted as a double-headed arrow representing the respectively measured distance. At least some of the actuators RA, DA, IA and sensors RS, DS, IS, which are explained in detail in the following paragraphs, are optional depending on the extent to which the damping caused by the parasitic mechanical disturbances is intended to be damped and are therefore depicted using dashed lines.

In addition to the actuators 37.1, 37.2 for closed-loop pose control of the mirror M3, the optical module 31 also comprises additional actuators RA, DA, IA which are designed to damp deformations of the mirror M3 caused by the parasitic mechanical disturbances, for example to reduce the three movement components of the mirror M3 caused by the parasitic mechanical disturbances and explained in relation to FIGS. 3A to 3C. The additional actuators comprise three types of actuators (frame actuator RA, deformation actuator DA, inertial actuator IA), which differ in the manner of supporting the respective reaction forces for example.

The frame actuator RA symbolized by a dashed double-headed arrow is supported on the force frame 35 like the actuators 37.1, 37.2 of the position actuator unit PA as well, and so the reaction forces arising when the actuator RA is controlled are absorbed by the force frame 35. In principle, the frame actuator RA can compensate all three movement components which are caused by parasitic mechanical disturbances and were explained in FIGS. 3A to 3C. However, supporting the reaction forces of the frame actuator RA on the force frame 35 and their possible propagation to the reference frame 34 once again causes indirect parasitic mechanical disturbances by way of the fed-back sensor signals and may lead to a closed-loop controller instability.

The deformation actuator DA is supported within the optical element M3 itself, i.e. it is connected on both sides to the optical element M3 and, in the embodiment shown in FIG. 4, is designed as an actuator, for instance an electrostrictive actuator, which acts parallel to the optically effective surface 33. An expansion or a contraction of the deformation actuator DA results in a deformation of the optically effective surface 33 in the form of bending, wherein, for reasons of clarity, FIG. 4 depicts only one deformation actuator DA as a representative for a multiplicity of deformation actuators DA for deforming the entire optically effective surface 33. The label as deformation actuator DA serves primarily to distinguish between the actuator types with different features and functions and is not restricted to a specific type of actuator types. The deformation actuator DA is able to compensate the movement components explained in FIG. 3B (quasi-static) and 3C (dynamic). On account of its arrangement, the deformation actuator DA causes no reaction forces on the force frame 35, which is why, in principle, the deformation actuator DA can additionally be used for avoiding reaction forces. In this case, the disturbance to be suppressed corresponds to the deformation that can be caused by the deformation actuator.

During its deflection, the inertial actuator IA is supported by a reaction mass 40 which is connected to the mirror M3 via a link 41 depicted as a spring. The principle of the inertial actuator IA is that of compensating deformations or rigid body movements caused by parasitic mechanical disturbances, wherein the frequency range of the inertial actuator depends on the properties of the link 41, for example on a predetermined rigidity and optional additional damping. The inertial actuator is only able to create forces above the resonant frequency of the mass/spring system since a deflection of the inertial actuator IA below the resonant frequency would only change the distance between the reaction mass 40 and the back side of the mirror. Thus, the reaction forces of the inertial actuator IA are not transferred to the system, i.e., the force frame 34 or any other structure. Thus, the inertial actuator IA is able to damp the dynamic movement component of the mirror M3, explained in FIG. 3C, and can be used for example for suppression of disturbances due to the reaction forces from other actuator types, especially the frame actuators RA, above a predetermined frequency, the so-called crossover frequency. The combination of an inertial actuator IA with a frame actuator RA or a deformation actuator DA is desirable in that the reaction forces of the position actuator unit PA in the higher frequencies for the closed-loop control, for instance above 50 Hz, are compensated by the inertial actuator IA. A precondition here is that the crossover frequency of the inertial actuator IA is also at 50 Hz. The reaction forces at the lower frequencies can be compensated by the respective closed-loop pose controller or closed-loop damping controller itself, which have a sufficient controller gain in this range.

The two other movement components (rigid body, quasi-static deformation) can also be compensated by an inertial actuator IA, wherein only the components above the crossover frequency can be compensated for as a matter of principle.

According to the disclosure, the illustrated types of additional actuators RA, DA, IA for damping deformations caused by the parasitic mechanical disturbances, in combination with the position actuator units PA known from the prior art, allow closed-loop pose control in six degrees of freedom while simultaneously damping the deformations caused by the parasitic mechanical disturbances. As a result, quasi-static and dynamic deformations of the optically effective surface can be reduced, or even compensated in full, and the effects thereof on the closed-loop control can be minimized by the feedback of the sensor signals influenced on account of the deformations and the reaction forces.

This is possible, for example, by the sensor signal decomposition according to the disclosure into a pose component for closed-loop pose control of the optical element and into a deformation component for damping the quasi-static and dynamic deformations, explained in detail in FIG. 5 and caused by the parasitic mechanical disturbances.

In an embodiment, there is an inertial actuator IA and, for damping the quasi-static and dynamic deformations, deformation actuators DA for each degree of freedom of the position actuator unit PA, whereby reaction forces no longer act on the mirror M3.

The optical module 31 also comprises additional sensors RS, DS, IS.

As a reference, the frame sensor RS, which for instance can be designed as an interferometer or capacitive sensor, uses the reference frame 34, which also serves as a reference for the position sensor unit PS.

For instance, the deformation sensor DS can be designed as a strain gauge or Bragg sensor, for example a fiber Bragg sensor, and thus directly senses a deformation of the mirror M3 or the optically effective surface 33. The deformation sensor DS is defined by the connection of both sides of the sensor with the mirror M3.

In a figurative sense, the inertial sensor IS, which can be designed as an acceleration sensor for example, measures in relation to an internal reference that is independent of the outside world. The sensors RS, DS, IS serve to sense the deformations of the optically effective surface 34 of the mirror M3 which are caused by the parasitic mechanical disturbances and are transmitted to the control circuit 32 (FIG. 5).

FIG. 5 shows a schematic illustration of a control circuit 32 according to the disclosure in an assembly 30 of an optical system such as the projection optical unit of the projection exposure apparatus 1 explained in FIG. 1.

The control circuit 32 is connected to the optical module 31, which was explained in FIG. 4, and comprises a closed-loop pose control 46 with a feedback control 44 and a feedforward control 45. The closed-loop pose control 46 controls the pose of the mirror M3 in six degrees of freedom using a closed-loop mechanism and at the same time suppresses the deformations caused by the parasitic mechanical disturbances, which were explained in FIGS. 3A to 3C, wherein a motion profile generator MPG of the closed-loop pose control 46 provides a time profile of a signal group q_{SW} with a position target value and a signal group a_{SW} with accelerations as input variables for each actuator 37.1, 37.2 (FIG. 4) of the position actuator unit PA.

The control circuit 32 also comprises an open-loop deformation control 47, which controls the additional actuators RA, DA, IA for deforming the optically effective surface 31 to a predetermined surface shape, wherein the surface shape is specified by a deformation profile generator DPG. The position signals q_{D} for the individual actuators PA, RA, DA, IA determined from the predetermined surface shape are fed to the closed-loop pose control 44 via two addition points 49.2, 49.3 downstream of the feedback control 44, wherein the static deformation is controlled using a closed-loop mechanism by way of the feedback control 44. A deliberate deformation of the optically effective surface 31 can be used for correcting the aberrations caused by other components of the projection exposure apparatus 1 for example.

The feedback control 44 of the closed-loop pose control 46 comprises a feedback controller 48 for closed-loop pose control of the mirror M3 and for damping the quasi-static and dynamic deformations of the mirror M3 caused by the parasitic mechanical disturbances; the mirror is depicted as a black box in FIG. 5 and explained in detail in the further figures. The feedback controller 48 comprises two inputs to which the position signals q_{SK}, q_{EM} are transmitted, wherein the position signals q_{SK} are used for closed-loop pose control of the rigid body of the mirror M3 and the position signals q_{EM} are used for damping the quasi-static and dynamic deformations of the mirror M3.

The position signals q_{SK}, q_{EM} are created in the feedback controller 48 by decomposing the signals q_{PS} and q_{AS} from the position sensor unit PS and the additional sensors RS, DS, IS into a pose component q_{SK} and a deformation component q_{EM}. The decomposition includes a modal decomposition, in which the modal eigenmodes of the mirror M3 are determined on the basis of the acquired position signals q_{PS}, q_{AS}. These comprise six rigid body movements, i.e., movements of the mirror M3 along an axis or a rotation of the mirror M3 about an axis, with the mirror M3 not being deformed in the process. These rigid body modes correspond to the pose component q_{SK}. The further eigenmodes determined from the position signals q_{PS}, q_{AS} include a deformation of the mirror M3 and are also referred to as flexible modes and correspond to the deformation component q_{EM}. Thus, following the decomposition, the pose component q_{SK} comprises the signals used for the closed-loop pose control of the mirror M3 in six mutually independent degrees of freedom, wherein the deformation component q_{EM} comprises the signals used for damping the quasi-static or dynamic deformations caused by the parasitic mechanical vibrations. The individual modes are independent of one another, and can thus also be controlled independently of one another using a closed-loop mechanism.

The lines depicted in FIG. 5, which have not been denoted by a separate reference sign for reasons of clarity, transmit a respective signal to each of the actuators PA, RA, DA, IA to be controlled or from each sensor PS, RS, DS, IS arranged on the mirror M3, i.e., a signal group with a number n_{PA}, n_{AA}, n_{PS}, n_{AS} of a plurality of signals, as depicted in the region of the mirror M3.

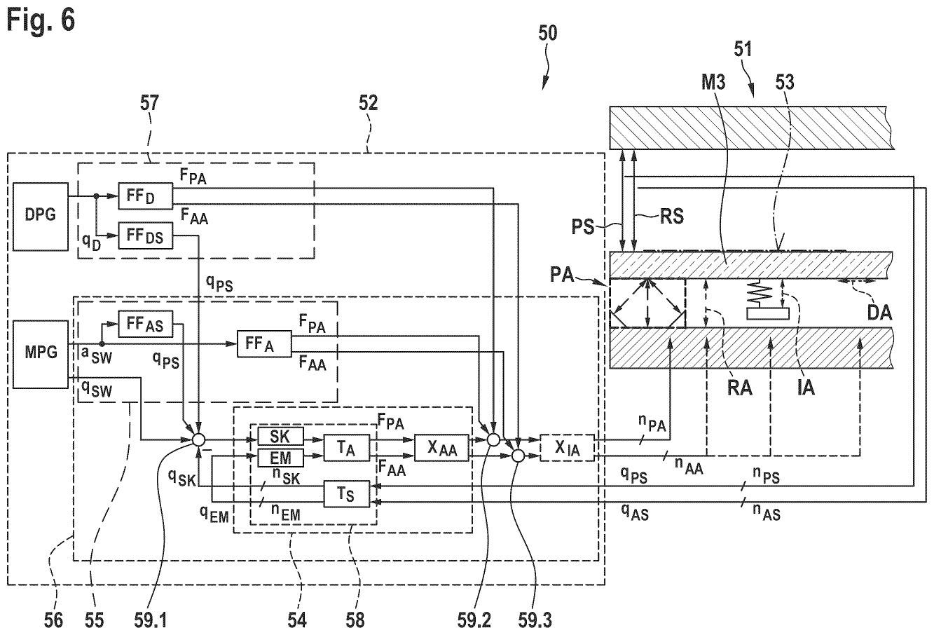

The position signals q_{SK} are determined for example from the lower frequency components in a range below 10 Hz to 100 Hz of the signals acquired by the position sensor unit PS and by the additional sensors RS, DS, IS, these frequency components being separated from the position values q_{PS} and q_{AS} by a frequency filter X_{IS}. By contrast, the position signals q_{EM} comprise the signals used to damp the deformations caused by the parasitic mechanical disturbances; these signals are determined for example from the higher frequency components above a range from 10 to 100 Hz, which are separated from the position values q_{PS} and q_{AS} by the frequency filter X_{IS}. They can be used to determine eigenfrequencies assigned to individual eigenmodes; this is explained in detail in FIG. 6. The feedback controller 48 thus has a closed-loop pose control for the rigid body of the mirror M3 and a closed-loop damping control, which damps individual eigenmodes of the mirror M3 caused by the parasitic mechanical disturbances.

The feedback control 48 also comprises two outputs, with one output outputting, via one line, the signals F_{PA} for controlling all actuators PA, RA, DA, IA for closed-loop pose control in the form of a positioning force and the other output outputting, via a further line, the signals F_{AA} for controlling all actuators RA, DA, IA for damping the quasi-static and dynamic deformations in the form of positioning forces. The signals F_{PA}, F_{AA} comprise a plurality of components which are created in different regions of the control circuit 32 and are combined via nodes 49.1, 49.2, 49.3. For reasons of clarity, all components of the signals transmitted to the actuators PA, RA, DA, IA are denoted merely by the reference signs F_{PA}, F_{AA}, and no distinction of the individual components is depicted.

Initially, the actuator signals F_{PA}, F_{AA} are split in a first frequency filter X_{AA} of the feedback control 44 such that the additional actuators RA, DA, IA do not exert any static forces on the mirror M3; i.e., the static forces used for the closed-loop pose control of the rigid body of the mirror M3 are transferred to the mirror M3 exclusively by the position actuator unit PA, whereby a static deformation of the optically effective surface 31 due to the additional actuators RA, DA, IA can be prevented. Nevertheless, the actuators RA, DA, IA make a contribution in the quasi-static and dynamic range to the closed-loop pose control of the mirror M3 assumed to be a rigid body. For instance, the frequency filter X_{AA} can be designed as a high-pass filter with a cutoff frequency of 30 Hz, whereby the gain for the additional actuators RA, DA, IA is zero at 0 Hz, i.e., no static forces act on the mirror M3.

Downstream of the frequency filter X_{AA} in the feedback control 44 and downstream of the addition of further actuator signals F_{PA}, F_{AA} from the feedforward controls 45, 47 explained further below, the actuator signals F_{PA}, F_{AA} are guided through a further frequency filter X_{IA} at the addition points 49.2, 49.3. This again divides the actuator signals F_{PA}, F_{AA} in frequency-dependent fashion, with the low-frequency components of the position actuator unit PA being assigned to the frame actuator RA and the deformation actuator DA and the higher frequency components being transferred to the inertial actuator IA. In the simplest case, the frequency filter X_{IA} can comprise a low-pass filter and a high-pass filter, with the crossover frequencies of the filters being determined such that the low-frequency components are located in a high-gain range of the feedback control 48, i.e., disturbances can be suppressed well. The inertial actuator IA suppresses the higher frequency components which cannot be suppressed, or cannot be suppressed sufficiently, by the feedback control 48 on account of the low gain at higher frequencies. The actuator signals F_{PA} and the actuator signals F_{AA} are transmitted to the position actuator unit PA and to the additional actuators RA, DA, IA, respectively, downstream of the frequency filter X_{IA}.

The closed-loop pose control 46 also comprises a feedforward control 45, which has two regions FF_{A}, FF_{AS}.

The first region FF_{A} determines an additional force for each of the actuators PA, RA, DA, IA of the optical module from the acceleration a_{SW} transmitted by the motion profile generator MPG.

The acceleration a_{SW} is determined on the basis of a mirror M3 movement trajectory based on the current target value q_{SW} and its subsequent target value q_{SW+1}. Thus, the movement trajectory describes the movement of the mirror 60 from the current target position q_{SW} to the subsequent target position q_{SW+1} which deviates from the current target position. Subsequently consistent time profiles of path and acceleration of the mirror M3 are determined from the movement trajectory, and the time profile of the acceleration is used in order to, according to F=m*a, determine the forces F_{PA}, F_{AA} used for changing the pose of the mirror 60 from the current target position q_{SW} to the subsequent target position q_{SW+1}.

The forces F_{PA}, F_{AA} determined thus are added at the addition points 49.2, 49.3 downstream of the frequency filter X_{AA} to the ascertained forces F_{PA}, F_{AA} from the feedback control 44, and so the positioning of the mirror M3 from the current target position q_{SW} to the subsequent target position q_{SW+1} is anticipated. This means that the pose deviation of the mirror M3 from the subsequent target position q_{SW+1} need not be sensed by the position sensor unit PS and then corrected by the feedback control 48; instead, this is already homed in on by the additional force F_{PA}, F_{AA} at the same time as the subsequent target value q_{SW+1} transmission. As a result, the feedback control 68 thus still only needs to correct the pose deviations caused by disturbances in the controlled system.

From the acceleration a_{SW}, the second region FF_{AS} determines a position error of the sensors in the position sensor unit PS; this error is referred to as path q_{PS} and caused by the deformation of the mirror M3 caused by the acceleration a_{SW}. This error q_{PS} is transmitted to the addition point 49.1 and added to the target value and the system deviation.

Additionally, the control circuit 32 comprises an open-loop deformation control 47, which receives a predetermined deformation profile, provided by a deformation profile generator DPG, of the optically effective surface 33 in the form of actuator travels q_{D} for the actuators PA, RA, DA, IA. The actuator travels q_{D} are transmitted to the two regions FF_{D} and FF_{DS} of the open-loop deformation control.

From the predetermined actuator travels q_{D}, the first region FF_{D} calculates the positioning forces F_{PA}, F_{AA} for the actuators PA, RA, DA, IA, which are fed to the addition points 49.2, 49.3 by the corresponding lines and which are processed further as explained further above.

In a manner comparable to the second region FF_{AS} in the feedforward control 45, the second region FF_{DS} determines the displacement of the sensors in the position sensor unit PS by the predetermined deformation of the optically effective surface. The value of the deviation is transmitted to the addition point 49.1 and considered in the closed-loop pose control as a result.

FIG. 6 shows a further embodiment of an assembly 50 according to the disclosure with an optical module 51 and a control circuit 52. The structure of the optical assembly 51 and the control circuit 52 largely corresponds to that of the assembly 31 and control circuit 32 described in FIG. 5, with elements with a meaningful correspondence being denoted by reference signs which have been increased by 10 or 20 in relation to FIG. 5. The embodiment in FIG. 6 comprises all types of additional actuators RA, DA, IA, explained in FIG. 5, and is distinguished by additional frame sensors RS, with only one additional frame sensor RS being depicted in FIG. 6 for reasons of clarity. The additional frame sensors RS sense the quasi-static and dynamic deformations caused by the parasitic mechanical disturbances and transmit these in the form of position signals q_{PS} and q_{AS} to the feedback controller 58. In a static transformation matrix T_{S} of the feedback controller 58, the position signals q_{PS} of the position sensor unit PS and the position signals q_{AS} of the additional frame sensors RS are transformed from a sensor coordinate system to a mirror coordinate system based on a reference point on the mirror M3. The reference point usually corresponds to an optical adjustment point on the optically effective surface 53 of the mirror M3. Due to the lack of inertial sensor IS, the frequency filter X_{IS} is not required and therefore not depicted in FIG. 6 either.

The transformation matrix T_{S} contains a respective line/column for each of the sensors in the position sensor unit PS and in the additional sensors RS and always is quadratic independently of the number of sensors PS, RS. The transformation matrix T_{S} decomposes the sensor signals q_{PS}, q_{AS} such that, firstly, a signal group q_{SK} with a signal for each of six degrees of freedom that are independent of one another in the coordinate system and, secondly, a signal group q_{EM} with a signal for each of a predetermined number of likewise mutually independent eigenmodes are created. As a result, each independent signal of the signal groups q_{SK}, q_{EM} has only one input value and one output value. According to the disclosure, the signals q_{SK} are transmitted to a closed-loop pose controller SK for closed-loop pose control of the mirror M3 assumed to be a rigid body, and the signals q_{EM} are transmitted to a closed-loop damping controller EM for damping the quasi-static and dynamic deformations caused by the parasitic mechanical disturbances. Both closed-loop controllers SK, EM are thus in the form of a single variable system or else in the form of a SISO (single input single output) system, whereby the closed-loop control is simplified vis-à-vis a multivariable system or MIMO (multiple input multiple output) system, in which a plurality of mutually dependent input variables and output variables are used.

In the closed-loop pose controller SK of the feedback controller 58, the six position signals q_{SK} of the position sensor unit PS are used for closed-loop pose control of the mirror M3 assumed to be a rigid body, wherein, in addition to the position actuator unit PA, the additional actuators RA, DA, IA are also used as final controlling elements for closed-loop pose control. By contrast, the sensor signals q_{EM} of the additional frame sensors RS are used in a second closed-loop damping controller EM which is formed in parallel with the closed-loop pose controller SK and serves for damping the quasi-static and dynamic deformations caused by the parasitic mechanical disturbances.

In addition to the additional actuators RA, DA, IA, the closed-loop damping controller EM likewise also uses the position actuator unit PA here as a final controlling element for damping the deformations. The closed-loop damping controller EM damps individual eigenmodes, especially eigenmodes that are used for the stability of the closed-loop control.

Thus, the feedback controller 58 comprises a known closed-loop pose controller SK with six final controlling elements controlled virtually independently of one another using a closed-loop mechanism and a closed-loop damping controller EM according to the disclosure, which damps individual eigenmodes, for instance a periodic second harmonic or third harmonic deformation of the mirror M3. The relevance of the eigenmodes depends on the respective eigenfrequency, with the damping only needing to consider those eigenmodes which adversely affect the bandwidth and hence the control quality of the closed-loop pose controller. The eigenmode damping reduces the influence of the dynamic deformations of the mirror M3 caused by the parasitic mechanical vibrations. As a result, the disturbances fed back to the closed-loop pose controller SK by the position sensor unit PS for example are reduced such that the pose of the mirror M3 assumed to be a rigid body can be controlled with a higher bandwidth with comparable stability using a closed-loop mechanism.

For both the position actuator unit PA and for the additional actuators RA, DA, IA, the closed-loop pose controller SK in this case outputs the actuator forces F_{PA} for closed-loop pose control which were determined by way of a known PID controller. For all actuators PA, RA, DA, IA, the closed-loop damping controller EM outputs the actuator forces F_{AA} for damping the quasi-static and dynamic deformations. The actuator forces F_{AA} are also determined by a PID controller, with the P-component and the I-component being optional. The static component of the actuator signal q_{AA} possibly caused by an I controller is filtered out downstream of the closed-loop pose controller SK by way of the frequency filter X_{AA} in order to avoid or at least reduce a static deformation of the mirror M3 and hence of the optically effective surface 53. Thus, the position actuator unit PA carries out a static rigid body movement of the mirror M3, while the additional actuators RA, DA, IA serve to damp the quasi-static and dynamic deformations caused by the parasitic mechanical disturbances. It is not possible to damp or prevent any components caused by reaction forces owing to the lack of an inertial sensor IS.

The actuator forces F_{PA}, F_{AA} determined by the feedback controller 58 are transformed from the mirror coordinate system into an actuator coordinate system by way of a further static transformation matrix T_{A} and transmitted to the frequency filter X_{AA}, which is explained in relation to FIG. 5. The further regions and functions of the control circuit 62 correspond to those explained in relation to FIG. 5 and will therefore not be explained again.

The additional actuators RA, DA, IA depicted in FIG. 6 are at least partly redundant; thus, only a frame actuator RA or a deformation actuator DA is used in addition to the inertial actuator IA for the purpose of suppressing the reaction force disturbances and of damping the deformations caused by the parasitic mechanical disturbances, with the deformation actuator DA representing an embodiment on account of using less installation space.

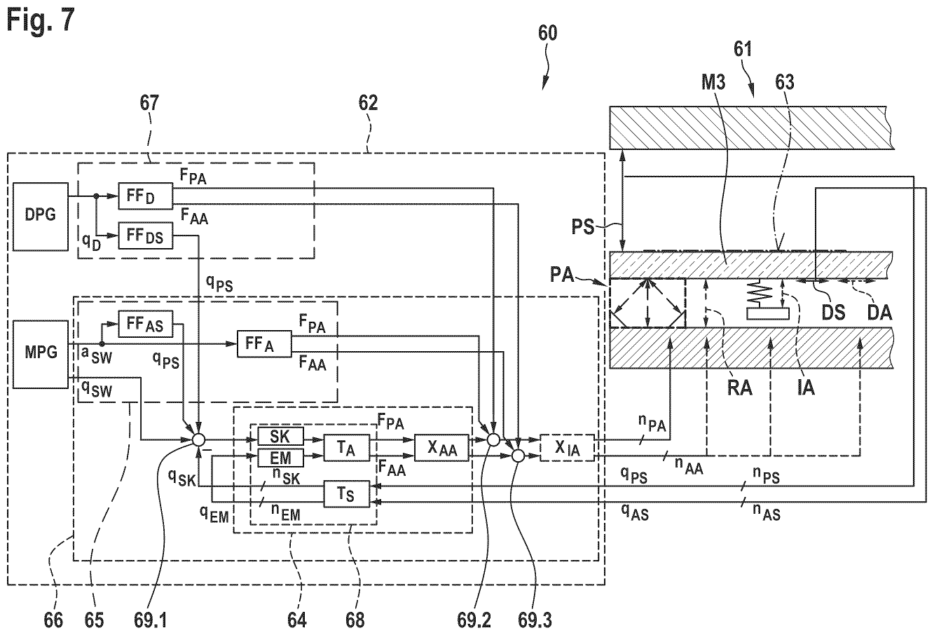

FIG. 7 shows a further embodiment of an assembly 60 according to the disclosure with an optical module 61 and a control circuit 62. The structure of the optical assembly 61 and of the control circuit 62 largely correspond to the assembly 51 and control circuit 52 described in FIG. 6, with elements with a meaningful correspondence being denoted by reference signs which have been increased by 10 in relation to FIG. 6. The embodiment in FIG. 7 comprises all types of additional actuators RA, DA, IA, explained in FIG. 5, and is distinguished by additional deformation sensors DS, with only one additional deformation sensor DS being depicted in FIG. 7 for reasons of clarity. The additional deformations sensors DS replace the frame sensors RS, explained in relation to FIG. 6, and in place of the latter sense the quasi-static deformations of the mirror M3 or its optically effective surface 63 caused by the parasitic mechanical disturbances.

All further regions and functions of the control circuit 62 are as explained in relation to FIG. 5 and will therefore not be repeated here.

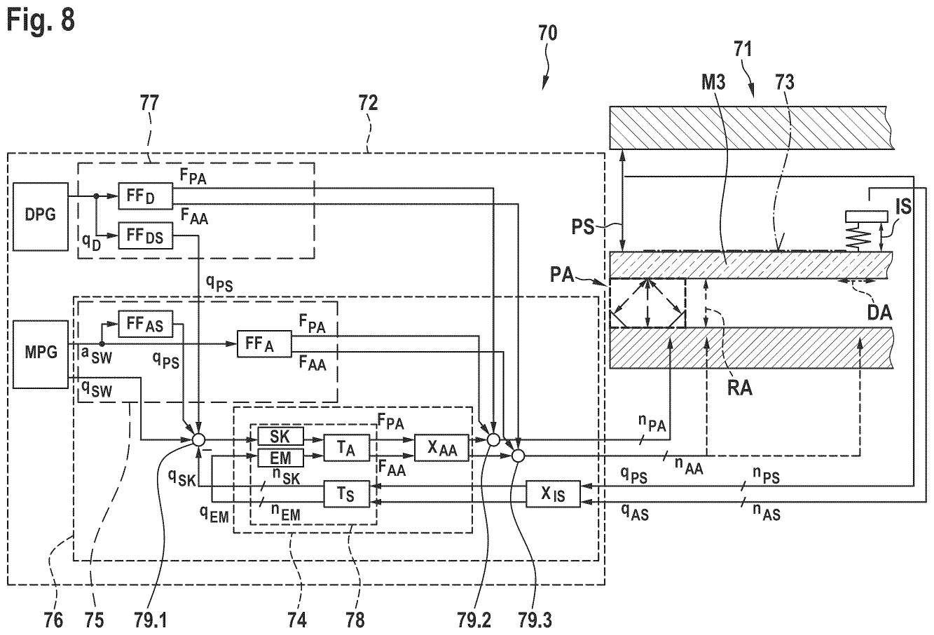

FIG. 8 shows a further embodiment of an assembly 70 according to the disclosure with an optical module 71 and a control circuit 72. The structure of the optical assembly 71 and of the control circuit 72 largely correspond to the assembly 61 and control circuit 62 described in FIG. 7, with elements with a meaningful correspondence being denoted by reference signs which have been increased by 10 in relation to FIG. 7.

The embodiment in FIG. 8 is distinguished by additional inertial sensors IS, with only one additional inertial sensor IS being depicted in FIG. 8 for reasons of clarity. The frequency filter X_{IS}, the function of which was already explained in relation to FIG. 5, is arranged in the path between the position sensor unit PS and the inertial sensors IS owing to the operational principle of the inertial sensor IS. The inertial sensor IS senses the reaction accelerations of all actuators acting on the mirror directly or indirectly, and so a suppression of the reaction force disturbances is also possible by the control circuit 72 depicted in FIG. 8, in addition to the deformation of the deformation caused by the parasitic mechanical disturbances which is possible in the control circuits 32, 52, 62. In this case, the reaction forces can be suppressed by way of the feedback controller 74, and so mechanical damping by way of an inertial actuator IA is not required. The embodiment depicted in FIG. 8 therefore also merely comprises a frame actuator RA and a deformation actuator DA. However, as explained further above, the inertial sensor IS is unable to sense any quasi-static or static deformations of the optically effective surface 73, as a result of which these cannot be compensated for in the embodiment shown in FIG. 8.

All further regions and functions of the control circuit 72 correspond to the regions and functions explained in relation to FIG. 5 and will therefore not be repeated here.

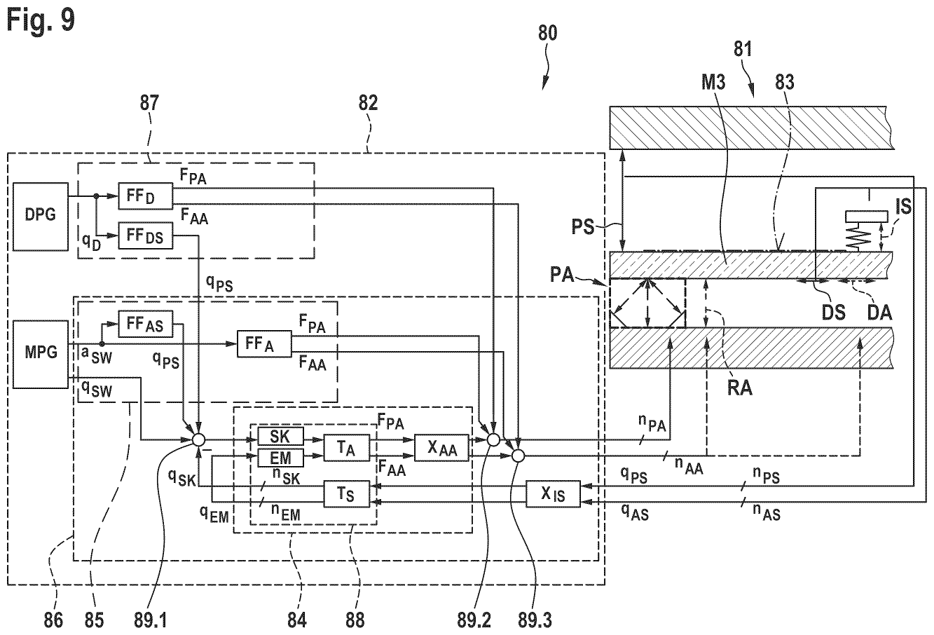

FIG. 9 shows a further embodiment of an assembly 80 according to the disclosure with an optical module 81 and a control circuit 82. The structure of the optical assembly 81 and of the control circuit 82 largely correspond to the assembly 71 and control circuit 72 described in FIG. 8, with elements with a meaningful correspondence being denoted by reference signs which have been increased by 10 in relation to FIG. 8. The embodiment shown in FIG. 8 is distinguished in that the optical assembly 81 comprises not only the additional inertial sensors IS, explained in relation to FIG. 8, but also the additional deformations sensors DS, explained in relation to FIG. 7, with in each case only one additional inertial sensor IS and one additional deformation sensor DS being depicted in FIG. 9 for reasons of clarity.

The two different sensors DS, IS can be used to sense and damp both the parasitic reaction forces and the deformations caused by the parasitic mechanical disturbances, wherein, as already explained in relation to FIG. 8, a frame actuator RA and a deformation actuator DA are sufficient in this respect, and it is possible to do without an additional inertial actuator IA.

All further regions and functions of the control circuit 82 correspond to the regions and functions explained in relation to FIG. 5 and will therefore not be repeated here.

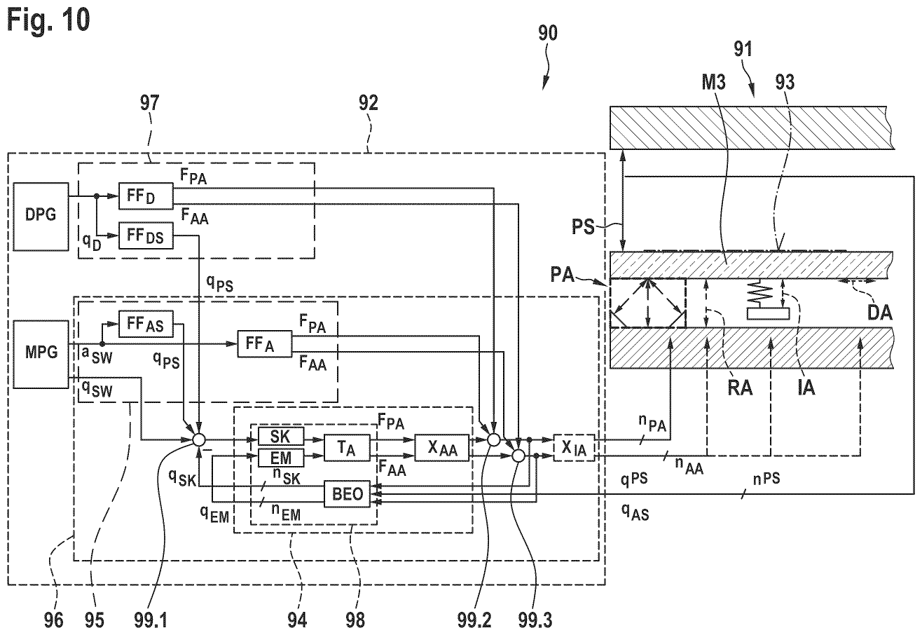

FIG. 10 shows a further embodiment of an assembly 90 according to the disclosure with an optical module 91 and a control circuit 92. The structure of the optical assembly 91 and of the control circuit 92 largely correspond to the assembly 81 and control circuit 82 described in FIG. 9, with elements with a meaningful correspondence being denoted by reference signs which have been increased by 10 in relation to FIG. 9. The embodiment depicted in FIG. 10 likewise comprises all types of additional actuators RA, DA, IA explained in FIG. 5 and is distinguished in that the optical module 91 does not comprise any additional sensors but only the sensors of the position sensor unit PS.

As a result, it is also possible to do without the frequency filter X_{IS}.

Instead of the static transformation matrix, the feedback controller 48 comprises a so-called observer, which allows a reconstruction of quasi-static deformations, vibration modes and rigid body modes from the sensor signals of the position sensor unit PS and the additional sensors. In control engineering, an observer is a system which reconstructs non-measurable variables (states) from known input variables, for instance actuator positioning forces F_{PA}, F_{AA}, and output variables (measured variables) in an observed reference system. To this end, it simulates the observed reference system as a model and uses a closed-loop controller to adjust the measurable state variables, which are therefore comparable to the reference system. The intention is thus to prevent a model from generating an error that grows over time, especially in the case of reference systems with integrating behavior. In the case of the embodiment depicted in FIG. 10, the observer reconstructs both the rigid body movement and the eigenmodes, which are explained further above, from the sensor values of the position sensor unit PS without being reliant on additional sensors. The use of an observer is desirable in that in comparison with the embodiments already explained, it is possible to reduce the number of desired sensors to the sensors desired for the feedback control 48 of the mirror M3; this may have a positive effect on the production costs. The model used by the observer can be designed adaptively, i.e., adapt over time.

All further regions and functions of the control circuit 92 correspond to the regions and functions explained in relation to FIG. 5 and will therefore not be repeated here.

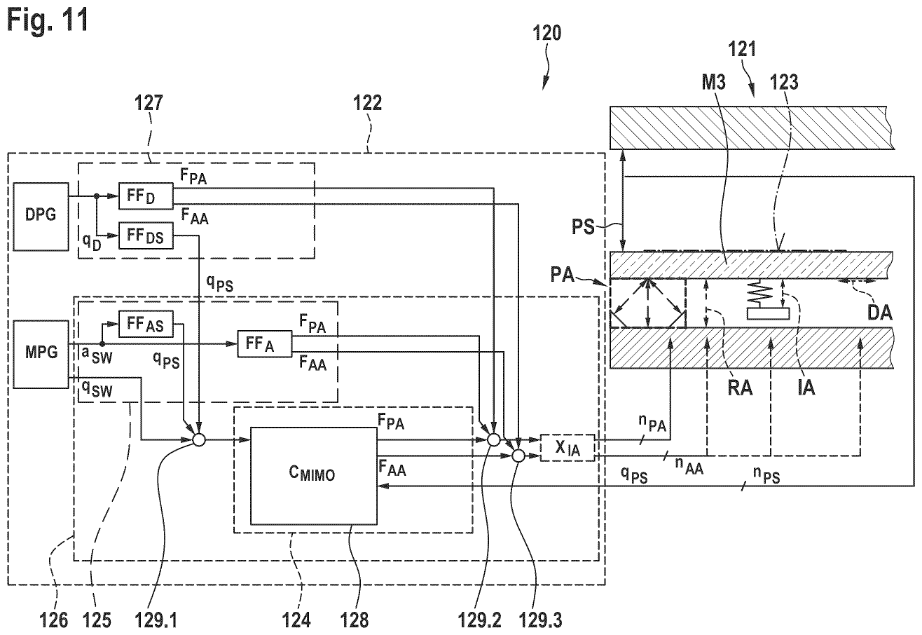

FIG. 11 shows a further embodiment of an assembly 120 according to the disclosure with an optical module 121 and a control circuit 122. The structure of the optical assembly 121 and of the control circuit 122 largely correspond to the assembly 91 and control circuit 92 described in FIG. 10, with elements with a meaningful correspondence being denoted by reference signs which have been increased by 30 in relation to FIG. 10. The embodiment depicted in FIG. 11 likewise comprises all types of additional actuators RA, DA, IA explained in FIG. 5 and is distinguished in that the feedback controller 128 is designed as a multivariable system rather than a single variable system used in the preceding embodiments. This system, which is also known as a MIMO (multiple input multiple output) system, comprises a plurality of inputs and outputs processed in a system, with the assumption being made that all values are related to one another or affect one another. The mathematical descriptions of the multivariable system are highly complex and are desirable in that, inter alia, the robustness of the closed-loop pose control 126 can be set as a parameter. The systems usually employed are known as H-infinity or as μ-synthesis. As in the embodiment with the observer too (FIG. 10), there is no need for additional sensors beyond the position sensor unit PS used for the closed-loop rigid body control, and this has a positive effect on the production costs.

The exemplary embodiments described in FIGS. 6 to 11 are only some of the possible combinations, without the disclosure being restricted thereto.

In addition to the position actuator units PA known from the prior art, at least one initial actuator IA and a further frame actuator RA or deformation actuator DA are used to damp all deformations caused by the parasitic mechanical disturbances and to suppress the reaction force disturbances. To establish the deformations caused by the parasitic mechanical disturbances, the control circuits 92, 122 (observer (FIG. 10) or multivariable system (FIG. 11)) according to the disclosure described in FIGS. 10 and 11 involve no further sensors in addition to the position sensor units PS known from the prior art.

The control circuits 52, 62, 72, 82 which, according to the disclosure, use a feedback controller 38, 48, 58, 68, 78, 88 supplemented by a closed-loop damping control as a closed-loop controller structure used at least one additional inertial sensor IS and at least one additional frame sensor RS or one additional deformation sensor DS to sense the deformations caused by the parasitic mechanical disturbances and sense the reaction forces. It may be desirable to implement a solution with actuators and sensors which are able to modify or sense the deformation of the optically effective surface relevant to the imaging quality as directly as possible, i.e., to the use of deformation actuators DA and deformation sensors DS. This has the feature that neither the actuators nor the sensors use a counter bearing or a reference outside of the optical element, whereby the arrangement of the actuators DA and sensors DS is facilitated on account of the in any case limited installation space availability and the accessibility. The number of additional actuators serving the purpose of sufficiently damping the arising eigenmodes, for example up to a frequency of 2 kHz, is greater than or equal to 1, such as greater than 15, for example greater than 50 actuators.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Assembly
31 Optical module
32 Control circuit
33 Optically effective surface
34 Reference frame
35 Force frame
37.1, 37.2 Position actuator unit actuators
38 Weight compensation
40 Inertial sensor reaction mass
41 Spring
42 Inertial sensor reference
43 Spring
44 Feedback control
45 Feedforward control
46 Closed-loop pose control
47 Closed-loop deformation control
48 Feedback controller
49.1-49.3 Addition points
50 Assembly
51 Optical module
52 Control circuit
53 Optically effective surface
54 Feedback control
55 Feedforward control
56 Closed-loop pose control
57 Closed-loop deformation control
58 Feedback controller
59.1-59.3 Addition points
60 Assembly
61 Optical module
62 Control circuit
63 Optically effective surface
64 Feedback control
65 Feedforward control
66 Closed-loop pose control
67 Closed-loop deformation control
68 Feedback controller
69.1-69.3 Addition points
70 Assembly
71 Optical module
72 Control circuit
73 Optically effective surface
74 Feedback control
75 Feedforward control
76 Closed-loop pose control
77 Closed-loop deformation control
78 Feedback controller
79.1-79.3 Addition points
80 Assembly
81 Optical module
82 Control circuit
83 Optically effective surface
84 Feedback control
85 Feedforward control
86 Closed-loop pose control
87 Closed-loop deformation control
88 Feedback controller
89.1-89.3 Addition points
90 Assembly
91 Optical module
92 Control circuit
93 Optically effective surface
94 Feedback control
95 Feedforward control
96 Closed-loop pose control
97 Closed-loop deformation control
98 Feedback controller
99.1-99.3 Addition points
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
120 Assembly
121 Optical module
122 Control circuit
123 Optically effective surface
124 Feedback control
125 Feedforward control
126 Closed-loop pose control
127 Closed-loop deformation control
128 Feedback controller
129.1-129.3 Addition points
M1-M6 Mirrors
q_{SW} Position target value
q_{PS} Position actuator position
q_{AS} Additional actuator position
q_{SK} Rigid body position measured values
q_{EM} Eigenmode position measured values
a_{SW} Acceleration target value
q_{D} Actuator travel for static deformation DPG
F_{PA} Position actuator forces
F_{AA} Additional actuator forces
PA Position actuator unit (6-DOF)
PS Position sensor unit (6-DOF)
RA Frame actuator
DA Deformation actuator
IA Inertial actuator
RS Frame sensor
DS Deformation sensor
IS Inertial sensor
MPG Motion profile generator
FF_{A} Acceleration feedforward controller
FF_{AS} Acceleration sensor compensation feedforward
T_{A} Actuator transformation matrix (static)
T_{S} Sensor transformation matrix (static)
SK Closed-loop pose controller for closed-loop pose control of the optical element assumed to be a rigid body
EM Closed-loop damping controller for damping dynamic deformations
BEO Eigenmode observer
C_{MIMO} MIMO (multiple input multiple output) controller
X_{AA} Frequency filter (static/dynamic forces)
X_{IA} Frame actuator and inertial actuator frequency filter
X_{IS} Frame actuator and inertial sensor frequency filter
n_{SK} Number of sensor signals for a closed-loop rigid body control
n_{EM} Number of sensor signals for a closed-loop eigenmode control
n_{PA} Number of actuators for a closed-loop rigid body control
n_{PS} Number of sensors for a closed-loop rigid body control
n_{AA} Number of additional actuators
n_{AS} Number of additional sensors
DPG Deformation profile generator
FF_{D} Force deformation feedforward control
FF_{DS} Sensor deformation feedforward control
K1, K2 Nodes

1. A method of controlling an optical module of an assembly in a semiconductor lithography projection exposure, the optical module comprising a first actuator configured to position the optical element, a second actuator configured to dampen deformations of the optical element caused by mechanical disturbances, and a sensor configured to determine a pose of the optical element, the method comprising:
decomposing a sensor signal relating to the pose of the optical element into a signal group comprising a pose component and a signal group comprising a deformation component;
positioning the optical element based on the pose component; and
damping the deformations based on the deformation component.

2. The method of claim 1, wherein the deformations comprise low frequency deformations and/or quasi-stationary deformations.

3. The method as of claim 1, wherein the sensor signal is decomposed using a static transformation matrix.

4. The method of claim 1, wherein the sensor signal is decomposed by an observer.

5. The method of claim 4, wherein the observer comprises an adaptive model.

6. The method of claim 1, wherein the sensor signal is decomposed by a multivariable system.

7. The method of claim 1, wherein:
a first closed-loop control is used to position the optical element based on the pose component;
a second closed-loop control is used to damping the deformations based on the deformation component; and
the second closed-loop control is independent of the first closed-loop control.

8. The method of claim 7, wherein each of the first and second closed-loop controls provide signals to control:
i) the first actuator to control the position of the optical element; and
ii) the second actuator to control damping the deformations.

9. The method of claim 8, wherein the signals to control the first actuator comprise a static component.

10. The method of claim 8, wherein:
the deformations comprise quasi-static deformations caused by parasitic mechanical disturbances and dynamic deformations caused by parasitic mechanical disturbances; and
the signals to control the second actuator are filtered so that the signals exclusively comprise quasi-static and/or dynamic components.

11. The method of claim 8, wherein the signals are decomposed into a first group for the first actuator and a second group for the second actuator.

12. The method of claim 1, wherein a parasitic component, caused by deformation of the optical element, of the position signal acquired by the sensor is determined.

13. The method of claim 12, wherein the parasitic component is fed back in a closed-loop.

14. A control circuit configured to control an optical element of an optical module of an assembly in a projection exposure apparatus for semiconductor lithography, the control circuit comprising:
a closed-loop pose control configured to use:
i) a fed-back sensor signal relating to a pose of the optical element to generate a first signal group as feedback for the closed-loop pose control of the optical element; and
ii) the fed-back sensor signal to generate a second signal group as feedback to dampen deformations of the optical element caused by parasitic mechanical disturbances.

15. The control circuit of claim 14, wherein the control circuit comprises a first transformation matrix configured to generate the first and the second signal groups.

16. The control circuit of claim 14, wherein the control circuit comprises an observer configured to generate the first and second signal groups.

17. The control circuit of claim 14, wherein the control circuit comprises a multivariable controller configured to generate the first and second signal groups.

18. The control circuit of claim 14, wherein the closed-loop pose control comprises:
i) a first closed-loop controller configured to position the optical element; and
ii) a second closed-loop controller configured to dampen the deformations.

19. An optical module comprising:
an optical element; and
a control circuit according to claim 14,
wherein the control circuit is configured to control the optical element.

20. (canceled)

21. An optical module, comprising:
an optical element;
a first actuator configured to position the optical element;
a second actuator configured to dampen deformations of the optical element caused by mechanical disturbances;
a position sensor configured to determine a pose of the optical element; and
a control circuit configured to control the optical element.

22. (canceled)

23. (canceled)
